(19) United States
(12) Patent Application Publication
(10) Pub. No.: US 2012/0068342 A1
(43) Pub. Date: Mar. 22, 2012

(54) ELECTRICALLY CONDUCTIVE ADHESIVE FOR TEMPORARY BONDING

(76) Inventor: Kevin J. Lee, Beaverton, OR (US)

(21) Appl. No.: 12/883,552

(22) Filed: Sep. 16, 2010

(51) Int. Cl. H01L 23/532; H01L 21/768

(52) U.S. Cl. 257/746; 438/610; 257/E21.597; 257/E23.155

(57) ABSTRACT

The present disclosure relates to the field of fabricating microelectronic devices, wherein a conductive adhesive is used as a temporary microelectronic wafer bonding adhesive to prevent damage to microelectronic devices resulting from electrical charge build-up on the microelectronic devices during the formation of through-silicon vias.

### BACKGROUND

Embodiments of the present description generally relate to the field of fabricating microelectronic devices and, more particularly, to a fabricating through-silicon vias for a microelectronic devices.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIGS. 1-9 illustrate side cross-sectional views of a process of forming a microelectronic device.

FIG. 10 illustrates a scanning electronic micrograph showing defects or damage in a microelectronic device caused by arcing.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of fabricating microelectronic devices, wherein a conductive adhesive is used as a temporary microelectronic wafer bonding adhesive to prevent damage to microelectronic devices resulting from electrical charge build-up on the microelectronic devices during the formation of through-silicon vias.

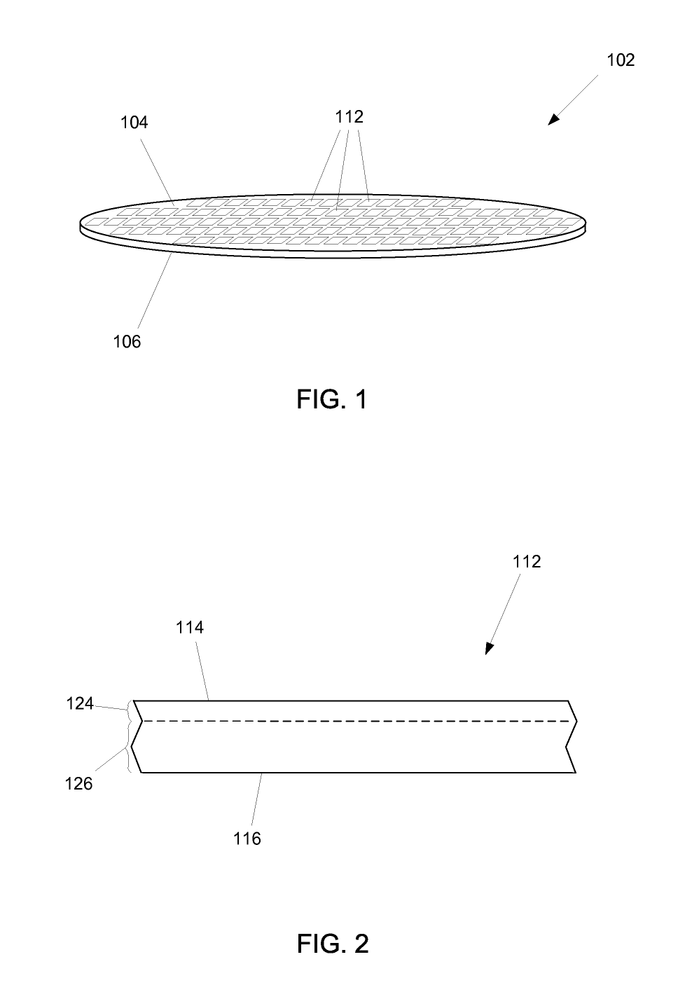

FIGS. 1-9 illustrate oblique and cross-sectional views of an embodiment of a process of forming microelectronic devices. As shown in FIG. 1, a microelectronic wafer 102 may be provided, wherein the microelectronic wafer 102 includes an active surface 104, an opposing back surface 106 that is substantially parallel to the microelectronic wafer active surface 104. The microelectronic wafer active surface 104 may have a plurality of microelectronic devices 112 formed therein and thereon, as will be understood to those skilled in the art. The microelectronic devices 112 may be any appropriate integrated circuit device including but not limited to a microprocessor (single or multi-core), a memory device, a chipset, a graphics device, an application specific integrated circuit, or the like.

As shown in FIG. 2, each microelectronic device 112 may include an active surface 114 (corresponding to the microelectronic wafer active surface 104) and an opposing back surface 116 (corresponding to the microelectronic wafer back surface 106) that is substantially parallel to the microelectronic device active surface 114. The microelectronic device 112 may have an active portion 124 proximate the microelectronic device active surface 114 and a substrate portion 126 extending from the microelectronic device active portion 124 to the microelectronic device back surface 116. As will be understood to those skilled in the art, the microelectronic device active portion 124 comprises at least a portion of the integrated circuitry of the microelectronic device 112.

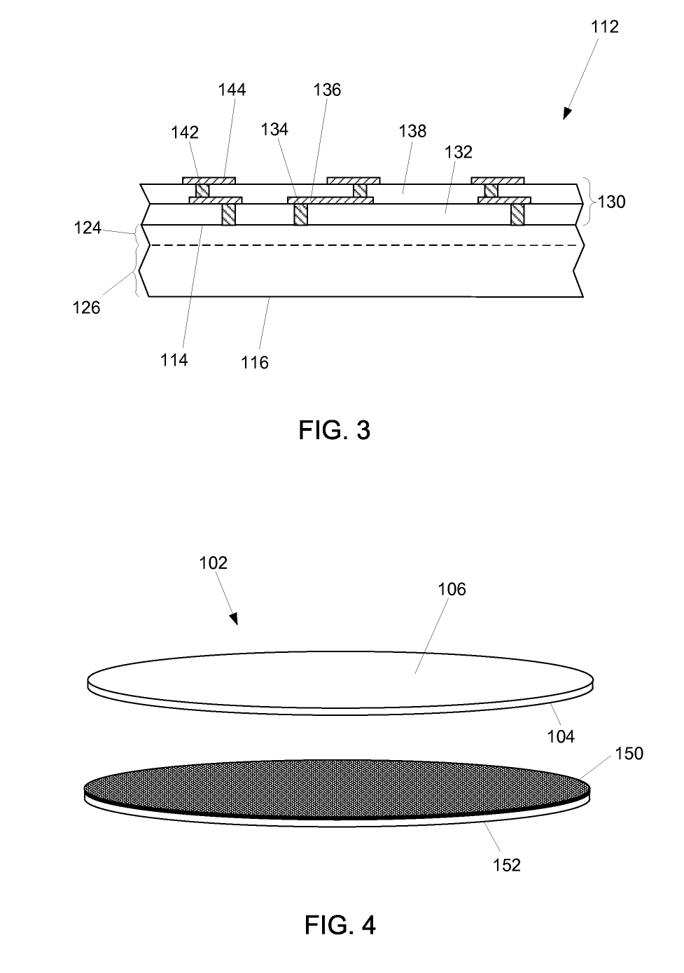

As shown in FIG. 3, an interconnect layer 130 may be formed on the microelectronic device active surface 114. The interconnect layer 130 may comprise a plurality of dielectric layers with conductive traces formed on each dielectric layer with conductive vias extending through each dielectric layer to connect the conductive traces, conductive lands, and/or electrical components, on different layers. Referring to FIG. 3, the interconnect layer 130 may comprise a first dielectric layer 132 formed on the microelectronic device active surface 114 with at least one first layer conductive via 134 extending through the first dielectric layer 132 and contacting integrated circuitry (not shown) adjacent the microelectronic device active surface 114. At least one first layer conductive traces 136 may be formed on the first dielectric layer 132 to contact at least one first layer conductive via 134. A second dielectric layer 138 may be formed over the first dielectric layer 132 and the first layer conductive traces 136. At least one second layer conductive via 142 may extend through the second dielectric layer 138 to connect at least one first layer conductive trace 136 to at least one contact land 144.

It is understood that although only one conductive trace layer and two dielectric layers are shown, the interconnect layer 130 may be any appropriate number of dielectric layers and conductive trace layers. The dielectric layer(s), such as the first dielectric layer 132 and second dielectric layer 138, may be formed by any technique known in the art and may be any appropriate dielectric material, including, but not limited to silicon dioxide, silicon nitride, and the like. The first layer conductive vias 134, the first layer conductive traces 136, the second layer conductive vias 142, and the contact lands 144 may be fabricated by any technique known in the art, including but not limited to plating and lithography, and may be made of any appropriate conductive material, including but not limited to copper, aluminum, silver, gold, or alloys thereof.

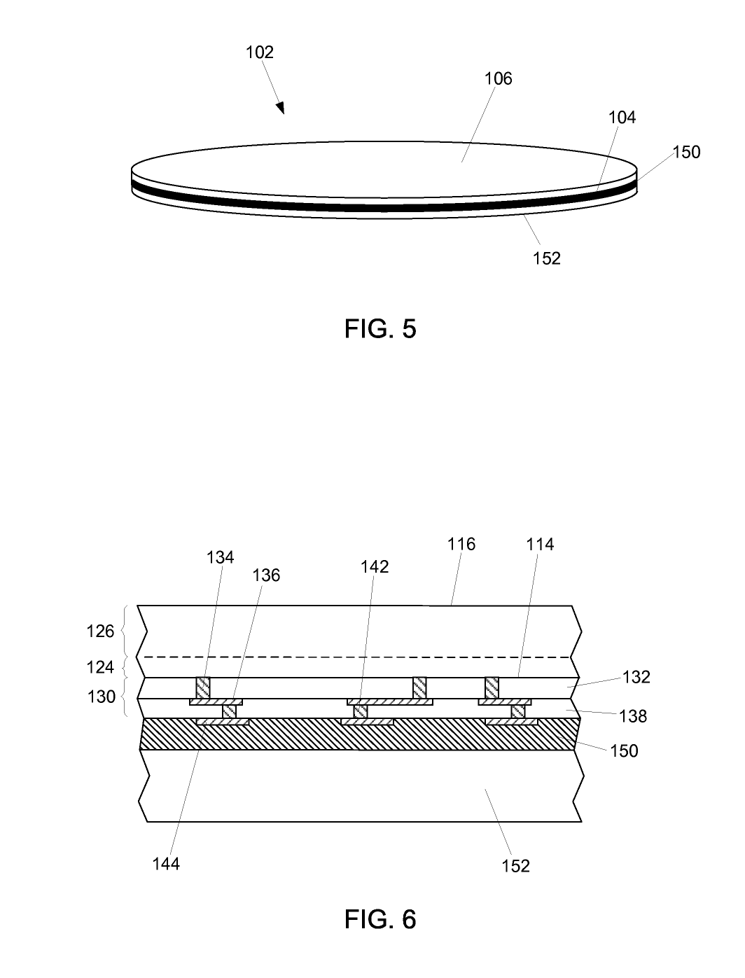

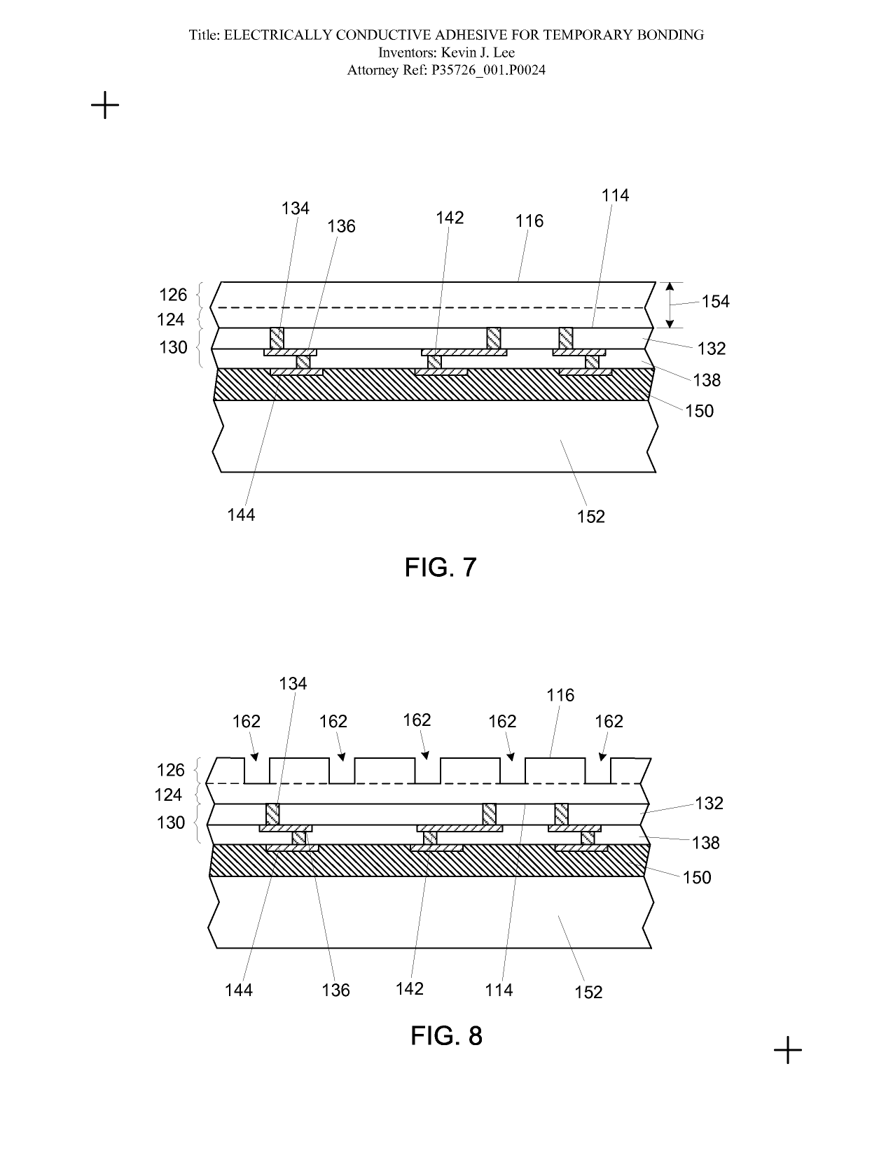

As shown in FIGS. 4-9, at least one conductive via may be formed to extend through the microelectronic device substrate portion 124 from the microelectronic device back surface 106 to the microelectronic device active portion 124 to contact integrated circuits (now shown) within the microelectronic device active portion 124. Such a conductive via configuration is known as a through-silicon via. To form the through-silicon via, an adhesive material 150 may be deposited on a temporary carrier 152, as shown in FIG. 4. The microelectronic wafer active surface 104 is placed on the adhesive material 150 to attach the microelectronic wafer 102 to the temporary carrier 152 as shown in FIGS. 5 and 6. Once the microelectronic wafer 102 is attached to the temporary carrier 152, the microelectronic wafer 102 may be thinned by removing a portion of the microelectronic wafer 102 from the microelectronic wafer back surface 106 to bring the microelectronic wafer back surface 106 closer to the microelectronic wafer active surface 104, as shown in FIG. 7. In one embodiment, the final thickness 154 of the microelectronic wafer is between about 40 um and 100 um.

As shown in FIG. 8, at least one opening 162 may be formed in microelectronic device substrate portion 126, wherein the openings 162 extend from the microelectronic device back surface 106 through to the microelectronic device active portion 124.

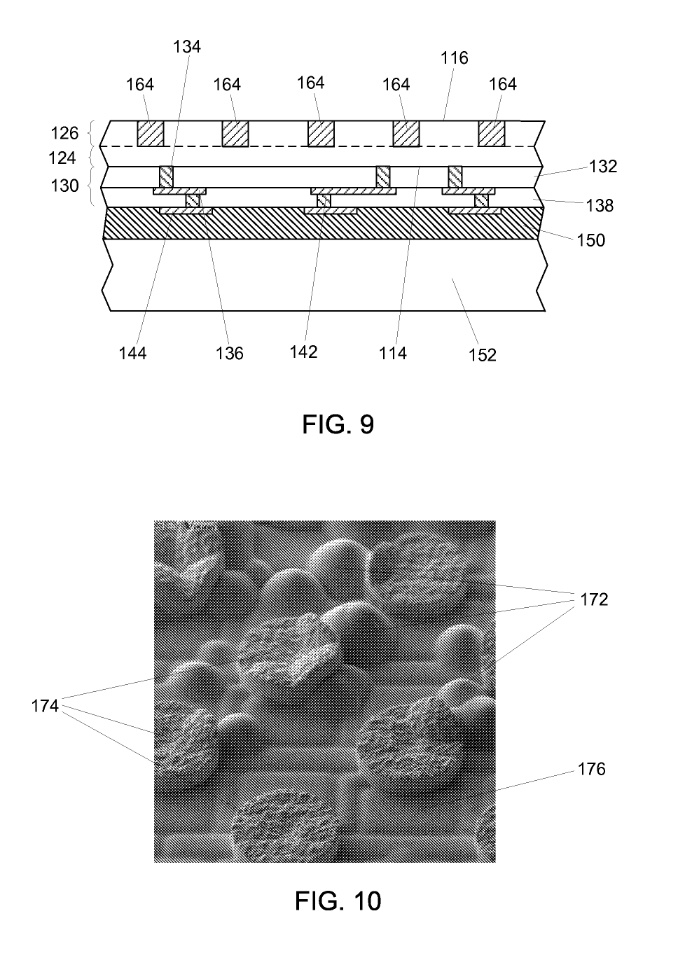

As shown in FIG. 9, the openings 162 (see FIG. 8) may be filled with a conductive material to form at least one through-silicon via 164. The through-silicon vias 164 may used to form electric communication routes with the integrated circuitry (not shown) in the microelectronic device active portion 124, as will be understood to those skilled in the art. The through-silicon vias 164 may be fabricated by any techniques known in the art, including, but not limited to drilling (laser and ion), lithography, etching, plating, deposition, and chemical planarization, and may be made of any appropriate conductive material, including but not limited to copper, aluminum, silver, gold, or alloys thereof.

Although the through-silicon vias 164 are shown as a single material, they may also include adhesion layers, barrier layers, and the like, as will be understood to those skilled in the art.

The numerous processing steps which may be employed to form the through-silicon vias 164 (drilling, lithography (including plasma and/or wet etch and resist strip), thin film deposition, plating, chemical mechanical polishing, and the like) may result in an electrical charge building up within the microelectronic wafer 102, particularly during high vacuum processes, such as sputter deposition and plasma etching. If the built up electrical charge is high enough, it can arc to a ground (such as the temporary carrier 152). The arcing can result in significant damage to the integrated circuitry (not shown) in the microelectronic device active portion 124, to the through-silicon vias 164, and/or to the interconnect layer 130. FIG. 10 is a scanning electron micrograph, which illustrates copper bumps 174 formed on the contact lands 144 (see FIG. 9) and a dielectric layer 176 formed on the interconnect layer 130 (see FIG. 9), wherein bumps or bubbles 172 (i.e., defects/damage) in the interconnecting layer 130 (see FIG. 9) caused by arcing can be seen.

In one embodiment of the present description, the adhesive material 150 may be substantially, electrically conductive. The conductive adhesive material 150 may form a conductive path from the microelectronic wafer 102 through the conductive adhesive material 150 to the temporary carrier 152 (which may be grounded). Thus, any electrical charge build-up will be discharged to ground. The conductive adhesive material 150 may be include, but is not limited to polyaniline doped with protonic acids (such as aqueous hydrochloric acid); poly˜3,4-ethylenedioxythiophene doped with polystyrene sulfonic acid; dodecyl benzene sulfonic acid doped polyaniline; camphor sulfonic acid doped polyaniline; and polyaniline doped with dinonylnaphthalene sulfonic acid.

In one embodiment of the present disclosure, the conductive adhesive material 150 may be a substantially non-conductive adhesive material, including but not limited to epoxy, polymer, or silicone resin, into which a conductive filler is dispersed. The substantially non-conductive adhesive material may be obtained commercially from Brewer Science, Inc., 2401 Brewer Drive, Rolla, Mo. 65401 USA (such as WaferBOND® HT-10.10), Thin Materials AG, Elsterstrasse 23, 82223 Eichenau, Germany (such as silicone elastomer), Tokyo Ohka Kogyo Co., Ltd., 150 Nakamaruko, Nakahara-ku, Kawasaki, Kanagawa 211-0012, Japan (such as TZNR-A series adhesives), HD Microsystems, 250 Cheesequake Road, Parlin, N.J. 08859 (such as HD-3007 polyimide), 3M, 3M Center, St. Paul, Minn. 55144-1000 (such as LC-3200, LC-4200, and LC-5200 acrylic-based adhesives), and General Chemical, 90 East Halsey Road, Parsippany, NU 07054 (such as GenTak® series adhesives). The conductive filler may include, but is not limited to, powders or particles of silver, gold, copper, nickel, aluminum, and carbon (i.e. graphite). Such conductive fillers are commercially available. The conductive filler may be between about 10 nm and 30 um in diameter. The conductive filler volume to non-conductive material volume may be between about 15% to 90%.

In one embodiment, the addition of the silver filler to an epoxy adhesive may increase the volume resistivity of the adhesive from about 1×10⁻¹² ohm-cm (no filler) to about 1×10⁴ ohm-cm (high filler content).

In another embodiment of the present description, the conductive adhesive material 150 may be the substantially non-conductive adhesive material, as previously discussed, into which small conducting spherical particles is dispersed. The conducting spherical particles may be microspheres of polymer or glass onto which nickel, silver, copper, gold or alloys thereof may be coated.

Once the fabrication of the through-silicon via 164 is complete, the interconnect layer 130 may be de-bonded from the temporary carrier 152, as known in the art. The de-bonding may be achieved through a variety of techniques, including but not limited to, heat, solvents, de-bonding agents, and the like.

It is also understood that the subject matter of the present description is not necessarily limited to specific applications illustrated in FIGS. 1-10. The subject matter may be applied to other microelectronic device fabrication applications, as will be understood to those skilled in the art. Furthermore, the subject matter may also be used in any appropriate application outside of the microelectronic device fabrication field.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A method of fabricating through-silicon vias, comprising:
providing a microelectronic wafer having an active surface and an opposing back surface; and
adhering the microelectronic wafer active surface to a temporary carrier with a conductive adhesive material.

2. The method of claim 1, wherein adhering the microelectronic wafer active surface to a temporary carrier with a conductive adhesive material comprises adhering the microelectronic wafer active surface to a temporary carrier with a conductive adhesive material comprising conductive filler dispersed in a substantially non-conductive adhesive material.

3. The method of claim 2, wherein adhering the microelectronic wafer active surface to a temporary carrier with a conductive adhesive material comprises adhering the microelectronic wafer active surface to a temporary carrier with a conductive adhesive material comprising conductive filler dispersed in a substantially non-conductive adhesive material, wherein the conductive filler comprises powders or particles of powders or particles of silver, gold, copper, nickel, aluminum, or carbon.

4. The method of claim 2, wherein adhering the microelectronic wafer active surface to a temporary carrier with a conductive adhesive material comprises adhering the microelectronic wafer active surface to a temporary carrier with a conductive adhesive comprising conductive filler dispersed in a substantially non-conductive adhesive material, wherein the conductive filler comprises microspheres coated with silver, nickel, copper, gold, or alloys thereof.

5. The method of claim 4, wherein adhering the microelectronic wafer active surface to a temporary carrier comprises adhering the microelectronic wafer active surface to a temporary carrier with a conductive adhesive comprising conductive filler dispersed in a substantially non-conductive adhesive material, wherein the conductive filler comprises polymer microspheres coated with silver, nickel, copper, gold, or alloys thereof.

6. The method of claim 4, wherein adhering the microelectronic wafer active surface to a temporary carrier comprises adhering the microelectronic wafer active surface to a temporary carrier with a conductive adhesive comprising conductive filler dispersed in a substantially non-conductive adhesive material, wherein the conductive filler comprises glass microspheres coated with silver, nickel, copper, gold, or alloys thereof.

7. The method of claim 2, wherein adhering the microelectronic wafer active surface to a temporary carrier with a conductive adhesive material comprises adhering the microelectronic wafer active surface to a temporary carrier with a conductive adhesive material comprising conductive filler dispersed in a substantially non-conductive adhesive material, wherein the substantially non-conductive adhesive material comprises epoxy, polymer, or silicone resin.

8. The method of claim 1, wherein the microelectronic wafer includes at least one microelectronic device having an active surface corresponding to the microelectronic wafer active surface and an opposing back surface corresponding to the microelectronic wafer back surface; and wherein the at least one microelectronic device includes an active portion proximate the microelectronic device active surface and a substrate portion extending from the microelectronic device active portion to the microelectronic device back surface.

9. The method of claim 8, further comprising forming at least one opening extending from the at least one microelectronic device back surface to the microelectronic device active portion.

10. The method of claim 8, further comprising disposing a conductive material within the at least one opening.

11. The method of claim 8, wherein disposing a conductive material within the at a least one opening comprises disposing copper, aluminum, silver, gold, or alloys thereof within the at least one opening.

12. The method of claim 10, further including removing the microelectronic wafer from the temporary carrier.

13. An intermediate structure comprising:
a microelectronic wafer having an active surface;
a temporary carrier; and
a conductive adhesive material adhering the microelectronic device active surface to the temporary carrier.

14. The intermediate structure of claim 13, wherein the conductive adhesive material comprises conductive filler dispersed in a substantially non-conductive adhesive material.

15. The intermediate structure of claim 14, wherein the conductive filler comprises powders or particles of powders or particles of silver, gold, copper, nickel, aluminum, or carbon.

16. The intermediate structure of claim 14, wherein the conductive filler comprises microspheres coated with silver, nickel, copper, gold, or alloys thereof.

17. The intermediate structure of claim 16, wherein the microspheres comprise polymer microspheres.

18. The intermediate structure of claim 16, wherein the microspheres comprise glass microspheres.

19. The intermediate structure of claim 14, wherein the substantially non-conductive adhesive material comprises further including epoxy, polymer, or silicone resin.
